(19) United States
(12) Patent Application Publication
(10) Pub. No.: US 2015/0235892 A1
(43) Pub. Date: Aug. 20, 2015

(54) WAFER CLAMP FOR CONTROLLING WAFER BOWING AND FILM STRESS

(71) Applicant: HGST Netherlands B.V., Amsterdam (NL)

(72) Inventors: Yunxiao Gao, Sunnyvale, CA (US); Cherngye Hwang, San Jose, CA (US); Xavier C. Lelong, San Jose, CA (US); Stefan Maat, San Jose, CA (US); Bruce W. Saxton, San Martin, CA (US); Charles G. Seegel, III, Sunnyvale, CA (US); Yong Shen, Saratoga, CA (US)

(21) Appl. No.: 14/183,291

(22) Filed: Feb. 18, 2014

(51) Int. Cl. H01L 21/687

(52) U.S. Cl. CPC H01L 21/68728; H01L 21/68721; H01L 21/68771

(57) ABSTRACT

A wafer clamp according to one embodiment includes an outer ring, and at least three members extending inwardly from the outer ring, each of the members having a contact area for engaging a wafer. A system includes a structure having at least one ring, each ring being for receiving a wafer, and a wafer clamp configured to clamp a wafer to each ring, the wafer clamp having an outer ring, and at least three members extending inwardly from the outer ring, each of the members having a contact area for engaging a wafer.

### FIELD OF THE INVENTION

The present invention relates to wafer clamping, and more particularly, invention relates to a wafer clamp that controls wafer bowing and film stress.

### BACKGROUND

Thin film products such as chips, magnetic heads, etc. are typically constructed of thin films deposited on a wafer.

To secure a wafer to a processing structure, conventional products rely on using a wafer mask which contacts the full circumference of the wafer near its perimeter. Under this design, the mask covers the full circumference of the wafer, extending roughly 2 mm or less inwards from the wafer's outer edge. The mask exerts a downward force on the periphery of the wafer, which biases the wafer against an O-ring beneath the wafer and positioned inside the location of the mask, e.g., 5 mm or more away from the wafer edge.

Detrimentally, this arrangement produces an undesirable cantilever effect on the wafer, thereby causing the wafer to how upward near its center as downward force is applied by the mask to the periphery of the wafer. Additionally, any high pressures exerted from beneath the wafer compound such bowing effects. As a result, such conventional products inevitably contribute significant stress to the wafer when bowed in the mask, in addition to compressive stress created by the wafer itself once it is removed from the mask.

### SUMMARY

A wafer clamp according to one embodiment includes an outer ring, and at least three members extending inwardly from the outer ring, each of the members having a contact area for engaging a wafer.

A system includes a structure having at least one ring, each ring being for receiving a wafer, and a wafer clamp configured to clamp a wafer to each ring, the wafer clamp having an outer ring, and at least three members extending inwardly from the outer ring, each of the members having a contact area for engaging a wafer.

Other aspects and advantages of the present invention will become apparent from the following detailed description, which, when taken in conjunction with the drawings, illustrate by way of example the principles of the invention.

### BRIEF DESCRIPTION OF THE DRAWINGS

For a fuller understanding of the nature and advantages of the present invention, as well as the preferred mode of use, reference should be made to the following detailed description read in conjunction with the accompanying drawings.

FIG. 1A is a top down view of a system according to one embodiment.

FIG. 1B is a partial cross-sectional view of the system of FIG. 1A taken along line 1B-1B.

FIG. 2A is a top down view of a system according to one embodiment.

FIG. 2B is a top down view of a system according to one embodiment.

FIG. 3 is a top down view of a system according to one embodiment.

FIG. 4 is an exploded view of the system of FIG. 3.

FIG. 5 is a method according to one embodiment.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

The following description discloses several preferred embodiments of disk-based storage systems and/or related systems and methods implementing a wafer clamp, as well as operation and/or component parts thereof, in various embodiments described herein, the wafer clamp that can be used to control wafer stress, in addition to improving thermal efficiency of the system.

In one general embodiment, a wafer clamp includes an outer ring, and at least three members extending inwardly from the outer ring, each of the members having contact area for engaging a wafer.

In another general embodiment, a system includes a structure having at least one ring, each ring being for receiving a wafer, and a wafer clamp configured to clamp a wafer to each ring, the wafer clamp having an outer ring, and at least three members extending inwardly from the outer ring, each of the members having a contact area for engaging a wafer.

As described above, conventional products rely on a wafer mask to secure wafers. However, such conventional products cause bowing of the wafer, thereby inducing undesirable stress in the wafer while in the mask as well as after being removed.

In sharp contrast, various embodiments described herein include a wafer clamping design that desirably reduces wafer stress.

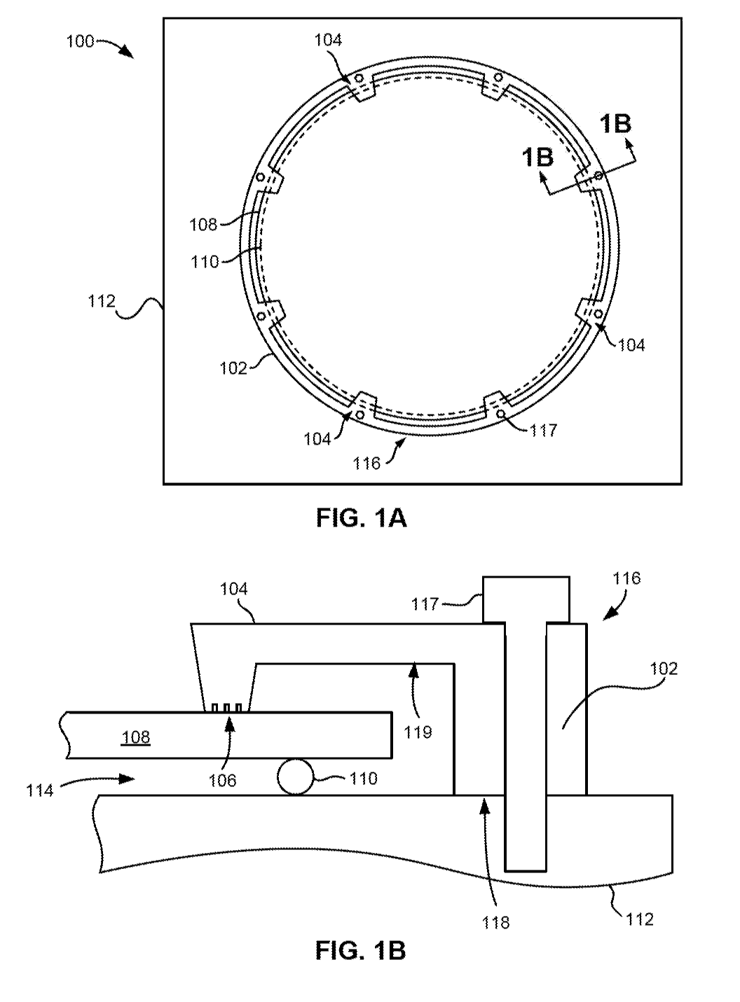

FIGS. 1A-1B depict a system 100, in accordance with one embodiment. As an option, the present system 100 may be implemented in conjunction with features from any other embodiment listed herein, such as those described with reference to the other FIGS. Of course, however, such system 100 and others presented herein may be used in various applications and/or in permutations which may or may not be specifically described in the illustrative embodiments listed herein. Further, the system 100 presented herein may be used in any desired environment.

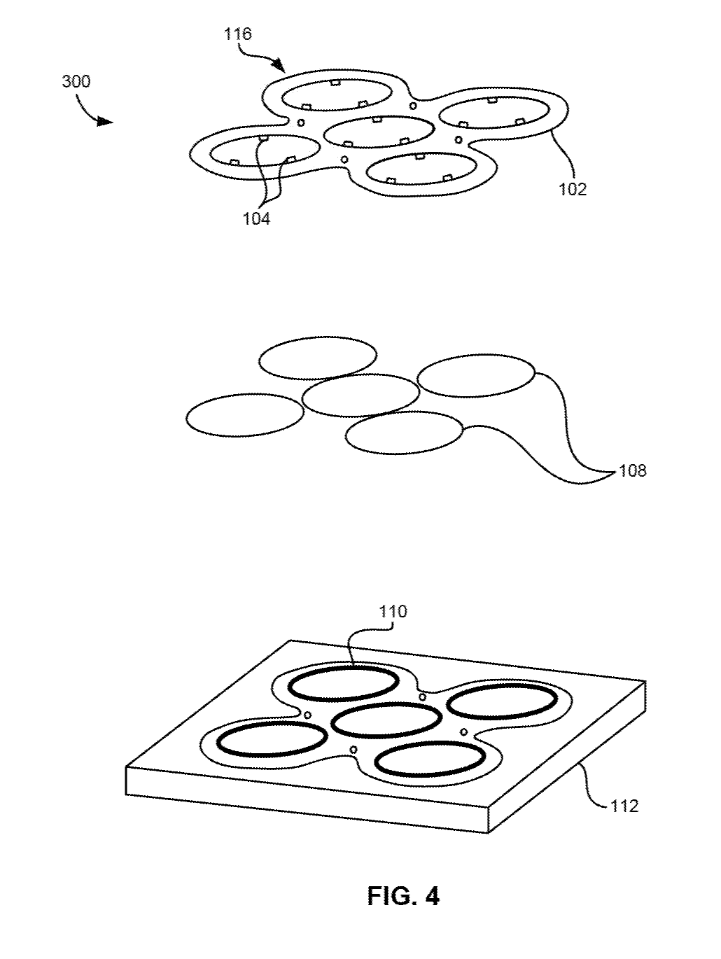

Looking to FIGS. 1A-1B, the system 100 includes a structure 112 having a ring 110. Note that the ring may have a round shape as shown, but other shapes are possible, including polygonal shapes. For simplicity, and by way of example only and without limitation, the ring 110 will be described in the various exemplary embodiments herein as an O-ring. The O-ring may be for receiving the wafer 108 as will be discussed in further detail below. As illustrated in the present embodiment, only one O-ring 110 is shown iii the system 100, however in other embodiments, a second, third, fourth, fifth, etc. O-ring may be included, e.g., for receiving, additional wafers. See e.g., FIG. 4. The O-ring may be of conventional construction and design in some embodiments.

With continued reference to FIGS. 1A-1B, the system 100 also includes a wafer clamp 116 configured to clamp the wafer 108 to the O-ring 110. As illustrated, the wafer clamp 116 has an outer ring 102, and members 104 extending inwardly from the outer ring 102. Dimensions of the outer ring 102 and/or members 104 of the wafer clamp 116 may vary, e.g., depending on the size of the wafer 108 to be clamped by the wafer clamp 116, diameter of the O-ring, etc. According to various embodiments, the wafer clamp 116 may be designed to clamp a 6 inch wafer, an 8 inch wafer, etc. Thus, the dimensions of the outer ring 102 and members 104 of the wafer clamp 116 may be, at least in part, wafer size dependent.

Moreover, each of the members 104 preferably has a planar or nonplanar contact area 106 for engaging the wafer 108. According to various approaches, the contact area 106 may be smooth (e.g. flat), textured, patterned, etc, depending on the desired embodiment. Contact areas 106 preferably may be placed on the same radial format away from the center of the wafer 108, but could have different arrangement formats depending on the embodiment. In the embodiment, shown, for example, the members 104 are evenly spaced about the periphery of the outer ring 102.

The lower surface 118 of the outer ring 102 adjacent the member does not engage the wafer 108. Preferably, a lower surface 119 of each member away from the contact area 106 does not engage the wafer 108.

It should also be noted that, although the wafer clamp 116 as illustrated in FIGS. 1A-1B includes eight members 104, in other approaches, the wafer clamp 116 may include more or fewer (preferably at least three) members 104, depending on the desired embodiment.

The wafer clamp 116 and/or components thereof may be constructed of any suitable material typically used in semiconductor processing equipment. Preferred materials are corrosion resistant, durable, and substantially rigid. In preferred embodiments, the wafer clamp 116 and/or the members 104 may be stainless steel or other rigid materials. The wafer clamp 116 and/or components thereof may be constructed as a monolithic piece, or of assembled parts. In some approaches, the wafer clamp 116 and/or components thereof may be fabricated using conventional techniques, such as machining, casting, etc.

The structure 112 may be configured to receive the wafer clamp 116, but is not limited thereto. According to various approaches, the water clamp 116 may be coupled to the structure 112 upon being received thereby, e.g., using fasteners such as bolts, clips, etc., adhesives; etc. Note that the fasteners 117 are shown adjacent the members 104 which ma improve the resilience of the members from deforming relative to the outer ring. In addition and/or alternatively, the fasteners may be placed in other locations.

The structure 112 may provide some additional functionality. For example, the structure 112 may function as an anode structure and/or a cathode structure, depending on the desired embodiment.

Moreover, iii some embodiments the structure 112 may function as a cooling plate. According to one approach, the structure 112 may function as a cooling plate by using backside gas cooling, e.g., to aid in cooling the wafer 108 during deposition thereon.

According to an exemplary embodiment, backside gas cooling may include dispersing gas, e.g., helium and/or other noble gas, in the sealed space 114 defined between the wafer 108, the structure 112, and the O-ring 110. As described above, the structure 112 may be configured to receive the wafer clamp 116, which presses the wafer 108 toward the structure 112. As a result, the force is transferred through the wafer 108 and structure 112 to the O-ring 110, which preferably aids in establishing, the sealed space 114 as seen in FIG. 1B. It follows that the O-ring 110 preferably includes a resiliently deformable material, such that the force exerted by the wafer clamp 116 causes the O-ring 110 to deform and create a tight seal at the interface between the O-ring 110 and the wafer 108, as well as the interface between the O-ring 110 the structure 112. Thus, the O-ring may include rubbers, soft plastics, clamps, elastics, etc., such that it may aid in forming the sealed space 114.

With continued reference to FIG. 1B, the structure 112 may create a pressure differential between a sealed space 114 and an environment above the wafer 108, e.g., as a result of a backside gas cooling process. According to different embodiments, the pressure differential may result from pressurizing the sealed space 114, and/or by inducing a vacuum above the wafer 108. Thus, the pressure differential between a sealed space 114 and an environment above the wafer 108 exerts a force on the wafer 108 directed away from the structure 112.

In some embodiments, the amount of pressure applied down onto the wafer 108 by the member at the contact area 106 is tuned/cantilevered in proportion with the force (caused by the pressure differential of sealed space 114) on the wafer 108, directed away from the structure 112, e.g., in order to optimize the net stress on the deposition prevent bowing in the wafer, balance upward and downward forces applied to the wafer 108, etc. Furthermore, the separation between the contact area 106 and the O-ring 110 (where the contact area 106 is located closer to the center of the wafer 108 than the O-ring 110) aids in increasing the downward pressure on the wafer 108, which may counterbalance the upward force the wafer 108 may experience particularly towards the center of the wafer 108, from pressurizing, the sealed space 114. Maintaining a flat wafer 108 may in some embodiments aid in maintaining film stress control; thus in different embodiments, orientations, sizes, dimensions, etc. of the wafer clamp 116 may be adjusted in order to maintain a “flat” wafer 108. Furthermore, in some embodiments, a flat wafer 108 may aid in cooling uniformity of a wafer 108, especially in the center of the wafer 108, as it is does not bow away from the structure 112.

It follows that in some embodiments, a force exerted on a wafer 108 by the contact areas 106 of the members 104 counteract a force exerted on a wafer 108 by the pressure differential. In some embodiments the pressure differential of sealed space 114 may be induced by gas pressure.

It should be noted that the contact area 106 of the members 104 which contact the wafer 108 may in some embodiments be nonplanar, e.g., may have a roughened, ridged, etched, etc. surface which may provide a desirable degree of contact on the wafer 108 surface. Furthermore, this surface preferably should not have pressure points that might cause damage to the surface of the wafer 108, e.g., sharp points that contact the wafer. In the embodiment shown in FIG. 1B, the contact area 106 of the member has channels formed therein.

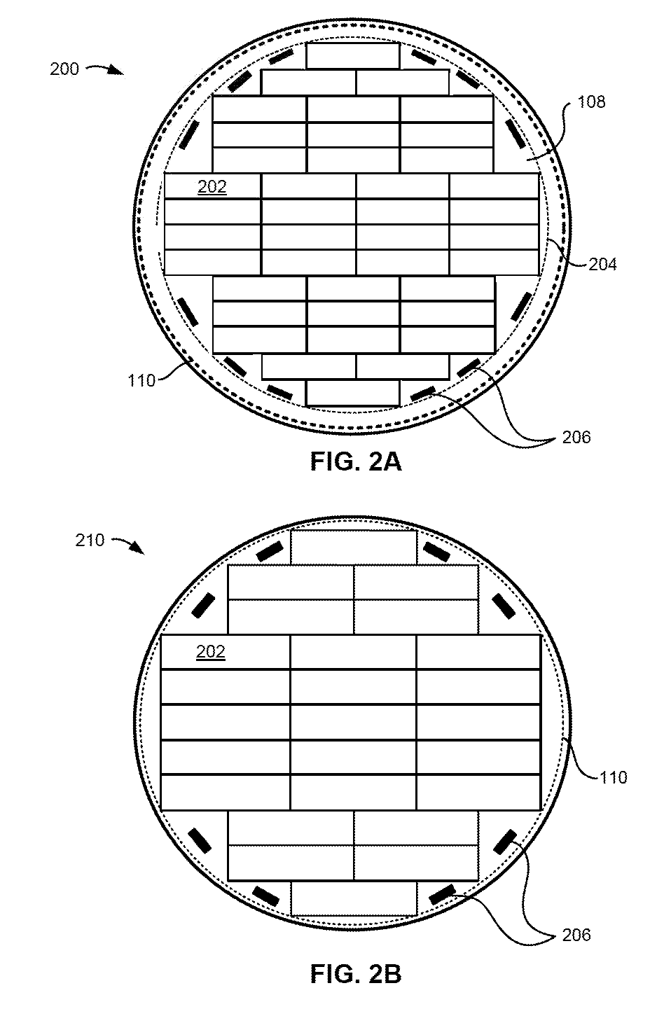

FIGS. 2A-2B depict contact area location layouts 200, 210, in accordance with two embodiments. As an option, the present contact area layouts 200, 210 may be implemented in conjunction with features from any other embodiment listed herein, such as those described with reference to the other FIGS., such as FIGS. 1A-1B. Accordingly, various components of FIGS. 2A-2B have common lumbering with those of FIGS. 1A-1B. Of course, however, such contact area layouts 200, 210 and others presented herein may be used in various applications and/or in permutations which may or may not be specifically described in the illustrative embodiments listed herein. Further, the contact area layouts 200, 210 presented herein may be used in any desired environment.

Referring to FIG. 2A, the contact area locations 206 are locations where the contact areas of the members engage the wafers. Such contact area locations 206 are illustrated as being positioned such that the contact areas of the members engage areas within a device circle 204 on a wafer 108. According to the present embodiment, the device circle 204 is an imaginary circle that touches one or more outermost device sites 202 on the wafer 108. Moreover, the device sites are those sites on the wafer 108 that have the thin film structures that will eventually be cut into individual device die.

Furthermore, the contact area locations 206 are preferably positioned to engage areas on the wafer 108 that are not device sites 202. As a result, the area of the wafer 108 on which the devices may be formed is not affected by the clamp.

Referring now to FIG. 2B, the contact area locations 206 may be positioned inside of a device circle 204. Moreover, the contact area locations 206 are also positioned inside a periphery defined by the O-ring 110.

It follows that, according to various embodiments, the configuration, number, orientation. etc. of the device sites 202 and/or contact area locations 206 may be designed to tune the force exerted by the wafer clamp 116 into the wafer 108. In some embodiments, one or more of the contact area locations 206 may be positioned at a greater distance inward from the O-ring to counteract a larger pressure differential (as described above), a thicker wafer, a fewer number of contact areas, etc. In other embodiments, one or more of the contact area locations 206 may be positioned closer to the O-ring to counteract a lower pressure differential, a thinner wafer, a fragile wafer material, a greater number of contact areas, etc., so long as they do not affect any device performance nearby.

Although one wafer clamp 116 and one O-ring 110 are illustrated in combination with the system 100 in FIGS. 1A-1B, in other approaches, a system may include any number of wafer clamps and/or O-rings e.g., at least one, two, at least two, at least three, a plurality, etc. depending on the desired embodiment. Moreover, the wafer clamps and/or O-rings may be positioned with any orientation relative to each other, depending on the desired embodiment.

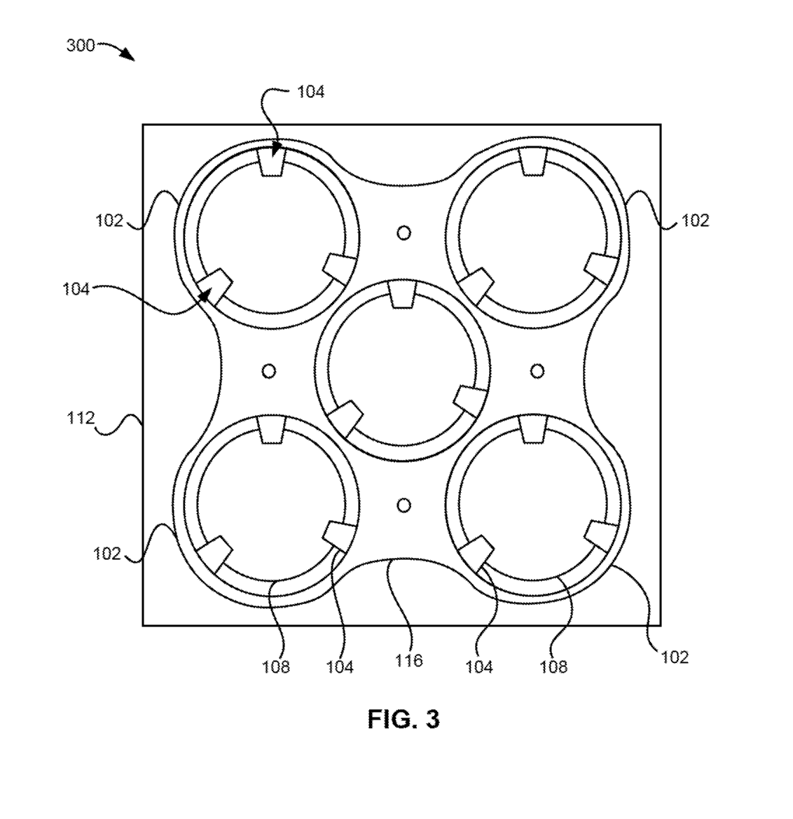

FIG. 3 depicts a system 300, in accordance with one embodiment. FIG. 4 illustrates an exploded view of the system 300. As an option, the present system 300 may be implemented in conjunction with features from any other embodiment listed herein, such as those described with reference to the other FIGS. Of course, however, such system 300 and others presented herein may be used in various applications and/or in permutations which may or may not be specifically described in the illustrative embodiments listed herein. Further, the system 300 presented herein may be used in any desired environment.

Referring to FIGS. 3 and 4, the wafer clamp 116 includes multiple outer rings 102, and three members 104 extending inwardly from each of the outer rings 102. It should be noted that, although the present wafer clamp 116 includes three members 104 extending inwardly from the outer ring 102, in other approaches, the wafer clamp 116 may include fewer or more members, depending on the desired embodiment.

Furthermore, each of the members 104 of the outer rings 102 preferably has a contact area (e.g., see 106 of FIGS. 2A-2B) for engaging a wafer 108. Thus the wafer clamp 116 may hold at least two wafers 108, and five wafers in the embodiment shown, e.g., for performing simultaneous processing steps thereon.

According to various embodiments, any of the outer rings 102 of the wafer clamp 116 may include any of the approaches described above with reference to the outer ring 102 of FIGS. 1A-1B.

The wafer clamp 116 may be coupled to a structure 112, in order to secure (e.g., clamp) the wafers 108 against an O-ring HO. According to various embodiments, the wafer clamp 116 may be coupled to the structure 112 at a lower surface (e.g., see 118 of FIG. 1B) using fasteners, adhesives, bolts, clips, etc.

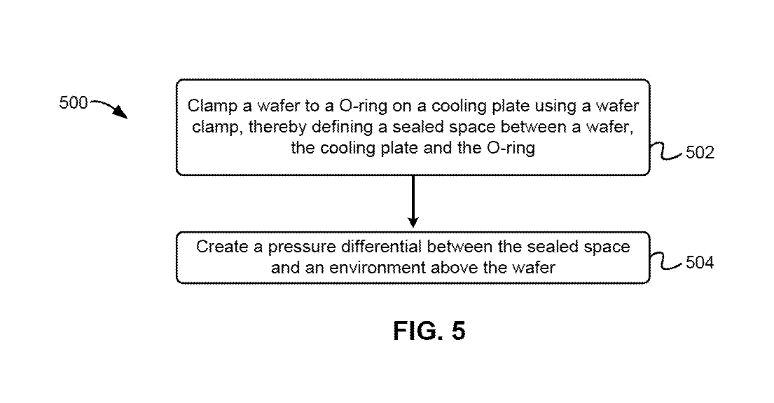

FIG. 5 depicts a method 500 of using the wafer clamp, in accordance with one embodiment. As an option, the present method 500 may be implemented in conjunction with features from any other embodiment listed herein, such as those described with reference to the other FIGS. Of course, however, such method 500 and others presented herein may be used in various applications and/or in permutations which may or may not be specifically described in the illustrative embodiments listed herein. Further, the method 500 presented herein may be used in any desired environment.

Referring now to FIG. 5, operation 502 of method 500 includes clamping a wafer to an O-ring on a structure using the wafer clamp. As noted above, fasteners or the like may be used to effect the clamping. This defines a sealed space between a wafer, the structure and the O-ring.

Operation 504 includes, creating a pressure differential between the sealed space and an environment above the wafer. As noted above, such pressure differential may be created by increasing a pressure in the sealed space and/or creating a vacuum in the environment above the wafer.

As described above, the structure may serve as a cooling plate, whereby a backside gas cooling process may be performed in the sealed space (e.g., see 114 of FIG. 1B). Moreover, the backside cooling gas pressure may result in the pressure differential between the sealed space and an environment above the wafer. However, the force exerted by the wafer clamp at the contact areas preferably neutralizes the opposing force resulting from the aforementioned pressure differential, thereby desirably preventing bowing of the wafers when clamped to a structure as described in operation 502.

According to another embodiment, negative bow may be added to the wafer 108 by increasing a clamping force exerted by the clamp. The introduction of negative bow to wafer 108 may allow tensile stress to be effectively created on the deposited film though bow relaxation after the wafer 108 is un-clamped.

It should be noted that methodology presented herein for at least some of the various embodiments may be implemented, in whole or in part, in computer hardware, software, by hand, using specialty equipment, etc. and combinations thereof.

Moreover, any of the structures and/or steps may be implemented using known materials and/or techniques, as would become apparent to one skilled in the art upon reading the present specification.

While various embodiments have been described above, it should be understood that they have been presented by way of example only, and not limitation. Thus, the breadth and scope of an embodiment of the present invention should not be limited by any of the above-described exemplary embodiments, but should be defined only in accordance with the following claims and their equivalents.

What is claimed is:

1. A wafer clamp, comprising:
an outer ring; and
at least three members extending inwardly from the outer ring, each of the members having a contact area for engaging a wafer.

2. The wafer clamp as recited in claim 1, wherein a lower surface of the outer ring does not engage a wafer.

3. The wafer clamp as recited in claim 1, wherein the contact area of the members are positioned to engage areas within a device circle on a wafer.

4. The wafer clamp as recited in claim 1, wherein the contact areas of the members are positioned to engage areas on a wafer that are not device sites.

5. The wafer clamp as recited in claim 1, further comprising at least one second outer ring coupled to the outer ring, and at least three members extending inwardly from each of the at least one second outer ring.

6. A method of using the wafer clamp of claim 1, the method comprising:
clamping a wafer to a ring on a cooling plate using the wafer clamp,
wherein a sealed space is defined between a wafer, the cooling plate and the ring; and
creating a pressure differential between the sealed space and an environment above the wafer.

7. The method as recited in claim 6, wherein the contact areas of the members engage a wafer inside a periphery defined by the ring.

8. The method as recited in claim 6, wherein a force exerted by the members on a wafer counteract a force exerted on the wafer by the pressure differential.

9. A system, comprising:
a structure having at least one ring, each ring being for receiving a wafer; and
a wafer clamp configured to clamp a wafer to each ring,
the wafer clamp having an outer ring, and at least three members extending inwardly from the outer ring, each of the members having a contact area for engaging a wafer.

10. The system as recited in claim 9, wherein the structure functions as an anode structure.

11. The system as recited in claim 9, wherein the structure functions as a cooling plate.

12. The system as recited in claim 11, wherein the structure creates a pressure differential between a sealed space and an environment above a wafer, wherein the sealed space is defined between the wafer, the structure for receiving the wafer clamp and the ring.

13. The system as recited in claim 9, wherein the structure creates a pressure differential between a sealed space and an environment above a wafer, wherein the sealed space is defined between the wafer, the structure for receiving the wafer clamp and the ring.

14. The system as recited in claim 13, wherein a force exerted on a wafer by the contact areas of the members counteract a force exerted on a wafer by the pressure differential.

15. The system as recited in claim 9, wherein a lower surface of the outer ring does not engage a wafer.

16. The system as recited in claim 9, wherein the contact areas of the members engage a wafer inside a periphery defined by the ring.

17. The system as recited in claim 9, wherein the contact areas of the members are positioned to engage areas within a device circle on a wafer.

18. The system as recited in claim 9, wherein the members are positioned to engage areas on a wafer that are not device sites.

19. The system as recited in claim 9, the wafer clamp further comprising at least one second outer ring coupled to the outer ring, and at least three members extending inwardly from each of the at least one second outer ring, each of the members of the at least one second outer ring having a contact area for engaging a wafer.

20. The system as recited in claim 19, wherein a lower surface of the at least one second outer ring does not engage a wafer, wherein the contact areas of the members of the at least one second outer ring engage the wafer inside a periphery defined by a second ring.
